(19) United States
(12) Patent Application Publication
(10) Pub. No.: US 2026/0090218 A1
(43) Pub. Date: Mar. 26, 2026

(54) DISPLAY DEVICE

(71) Applicant: LG Display Co., Ltd., Seoul (KR)

(72) Inventors: Soobin LEE, Seoul (KR); Jongmoo HA, Gimpo-si (KR)

(73) Assignee: LG Display Co., Ltd., Seoul (KR)

(21) Appl. No.: 19/272,895

(22) Filed: Jul. 17, 2025

(30) Foreign Application Priority Data
Sep. 23, 2024 (KR) 10-2024-0128176

(51) Int. Cl. H10K 59/124; G06F 3/041; H10K 59/131; H10K 59/40; H10K 102/00

(52) U.S. Cl. CPC H10K 59/124; G06F 3/0412; G06F 3/04164; H10K 59/131; H10K 59/40; G06F 2203/04102; H10K 2102/311

(57) ABSTRACT

A display device includes a substrate including a display area, a first non-display area, a bending area extending from the first non-display area, and a second non-display area extending from the bending area. A plurality of light emitting diodes is in the display area, and a touch electrode unit is located above the diodes. The first non-display area includes a plurality of power link lines covered by a planarization layer. A plurality of touch link lines is electrically connected to the touch sensing unit and the power link lines through contact holes in the planarization layer. A touch buffer layer which is disposed between the light emitting diodes and the touch sensing unit, and on the planarization layer in the first non-display area. In the portion of the first non-display area closer to the display area, the touch link lines and the touch buffer layer are on the same plane.

### CROSS-REFERENCE TO RELATED APPLICATIONS

This application claims the priority of Korean Patent Application No. 10-2024-0128176 filed on Sep. 23, 2024, in the Korean Intellectual Property Office, the disclosure of which is incorporated herein by reference.

### BACKGROUND

### Technical Field

The present disclosure relates to a display device, and more particularly, to a display device in which a defect that a touch electrode unit does not normally operate is improved.

### Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, a light emitting display device is a self-emitting display device so that a separate light source is not necessary, which is different from the liquid crystal display device. Therefore, the light emitting display device may be manufactured to have light weight and small thickness. Further, since the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### BRIEF SUMMARY

Various embodiments of the disclosed display device improve touch accuracy and structural reliability by addressing issues related to shared power sources and mechanical stress in flexible regions. In one aspect, both the touch link lines and the touch buffer layer are arranged on the same plane above the planarization layer, particularly in the non-display area. This configuration reduces the likelihood of film lifting and cracking caused by thermal expansion or repeated bending, thereby minimizing touch malfunctions and enhancing the operational life of the device.

The device also includes a multilayer encapsulation structure that combines organic and inorganic materials, along with a molding member that seals the assembly to protect against environmental factors such as moisture and oxygen. The use of buffer layers, resin-based micro coating in the bendable regions, and the separation of electrical pathways for touch and power functions contribute to the stability and consistent performance of the display under mechanical and environmental stress.

Some embodiments of the present disclosure provide a display device which minimizes an erroneous operation of a touch electrode unit in a power source contact area caused by commonly using a touch power source and a power source of a light emitting diode.

Some embodiments of the present disclosure provide a display device which relieves a crack caused by film lifting between heterogeneous insulating layers due to contraction and expansion of a molding member.

Technical benefits of the present disclosure are not limited to the above-mentioned benefits, and other benefits, which are not mentioned above, can be clearly understood by those skilled in the art from the following descriptions.

According to an aspect of the present disclosure, a display device includes: a substrate including a display area, a first non-display area surrounding the display area, a bending area extending from the first non-display area, and a second non-display area extending from the bending area; a plurality of light emitting diodes on the substrate in the display area; a touch electrode unit on the plurality of light emitting diodes in the display area; a plurality of power link lines on the substrate in the first non-display area; a planarization layer on the plurality of power link lines in the first non-display area; a plurality of touch link lines electrically connected to the touch sensing unit and electrically connected to the plurality of power link lines through a plurality of contact holes of the planarization layer in the first non-display area; and a touch buffer layer which is disposed between the plurality of light emitting diodes and the touch sensing unit in the display area and is disposed on the planarization layer in the first non-display area, and in the first non-display area which is closer to the display area than the plurality of contact holes of the planarization layer, the plurality of touch link lines and the touch buffer layer are disposed on the same plane on the planarization layer.

Other detailed matters of the exemplary embodiments are included in the detailed description and the drawings.

According to the present disclosure, a plurality of touch link lines and a touch buffer layer are disposed on the same plane to improve an erroneous operation of the touch electrode unit.

According to the present disclosure, the plurality of touch link lines and the touch buffer layer are disposed on the planarization layer to be in direct contact with each other to block a crack which may be caused by the film lifting.

According to the present disclosure, the damage of the touch electrode unit is minimized to improve the lifespan of the display device to be driven at a low power.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure;

FIG. 2 is a cross-sectional view of one sub pixel of a display device according to an exemplary embodiment of the present disclosure;

FIG. 3 is a cross-sectional view illustrating a bent state of a display device according to an exemplary embodiment of the present disclosure;

FIG. 4 is an enlarged plan view of an area A of FIG. 1;

FIG. 5 is a cross-sectional view taken along K-K′ of FIG. 4;

FIG. 6 is an enlarged plan view of an area B of FIG. 4;

FIG. 7A is a cross-sectional view taken along C-C′ of FIG. 6;

FIG. 7B is a cross-sectional view taken along D-D′ of FIG. 6;

FIG. 8 is a cross-sectional view of a display device according to another exemplary embodiment of the present disclosure;

FIG. 9A is a cross-sectional view taken along E-E′ of FIG. 8;

FIG. 9B is a cross-sectional view taken along F-F′ of FIG. 8;

FIG. 10 is a cross-sectional view of a display device according to still another exemplary embodiment of the present disclosure;

FIG. 11A is a cross-sectional view taken along G-G′ of FIG. 10;

FIG. 11B is a cross-sectional view taken along H-H′ of FIG. 10;

FIG. 12 is a cross-sectional view of a display device according to still another exemplary embodiment of the present disclosure;

FIG. 13A is a cross-sectional view taken along I-I′ of FIG. 12; and

FIG. 13B is a cross-sectional view taken along J-J′ of FIG. 12.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only,” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

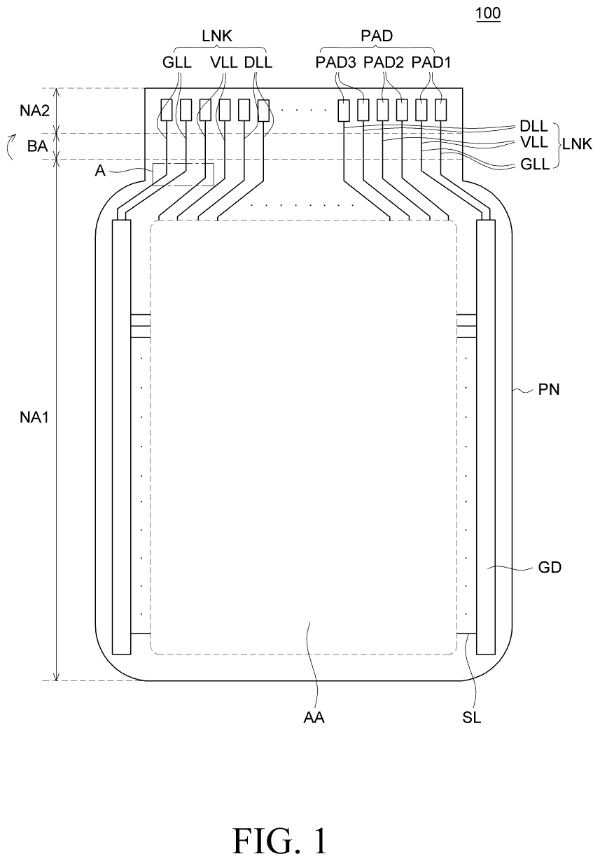

FIG. 1 is a schematic plan view of a display device according to an exemplary embodiment of the present disclosure. In FIG. 1, for the convenience of description, among various components of the display device 100, only a display panel PN, a plurality of pads PAD, a plurality of link lines LNK, a plurality of scan lines SL, and a gate driver GD are illustrated.

Referring to FIG. 1, the display device 100 according to the present disclosure includes a display panel PN, a plurality of pads PAD, a plurality of link lines LNK, a plurality of scan lines SL, and a gate driver GD.

The display panel PN is a panel for displaying images to a user. In the display panel PN, a light emitting diode which displays images, a driving element which drives the light emitting diode, and wiring lines which transmit various signals to the light emitting diode and the driving element may be disposed. Therefore, the display panel PN may include a substrate for supporting various components of the display device 100.

The light emitting diode may be defined in different manners depending on the type of the display panel PN. For example, when the display panel PN is an organic light emitting display panel PN, the light emitting diode may be an organic light emitting diode which includes an anode, an organic emission layer, and a cathode. For example, when the display panel PN is a liquid crystal display panel, the light emitting diode may be a liquid crystal display element. Hereinafter, even though the display panel PN is assumed as an organic light emitting display panel, the display panel PN is not limited to the organic light emitting display panel.

The display panel PN may include a display area AA and a non-display area.

The display area AA is an area where images are displayed in the display panel PN. In the display area AA, a plurality of sub pixels which configures the plurality of pixels and a driving circuit for driving the plurality of sub pixels may be disposed.

The plurality of sub pixels is minimum units which configure the display area AA and a light emitting diode may be disposed in each of the plurality of sub pixels. For example, an organic light emitting diode which includes an anode, an organic emission layer, and a cathode may be disposed in each of the plurality of sub pixels SP, but it is not limited thereto. Further, a driving circuit for driving the plurality of sub pixels may include a driving element and a wiring line. For example, the driving circuit may be configured by a thin film transistor, a storage capacitor, a gate line, and a data line, but is not limited thereto.

The non-display area is an area in which no image is displayed. The non-display area may refer to an outer peripheral portion of the display panel PN which surrounds the display area AA. In the non-display area, various wiring lines and circuits for driving an organic light emitting diode in the display area AA are disposed. For example, in the non-display area, the gate driver GD, a data driver, a plurality of link lines LNK, and a plurality of pads PAD may be disposed. A non-display area NA in which an image is not displayed may be a bezel area and exemplary embodiments of the present disclosure are not limited thereto.

The non-display area includes a first non-display area NA1, a bending area BA, and a second non-display area NA2.

The first non-display area NA1 is an area which surrounds the display area AA and extends from the display area AA. The bending area BA may extend from one side of the first non-display area NA1 and may be bent in a direction denoted by an arrow illustrated in FIG. 1. The second non-display area NA2 is an area which extends from the bending area BA to be disposed below the display area AA. In the meantime, like the display panel PN, the substrate 110 may include the display area AA, the first non-display area NA1 which surrounds the display area AA, a bending area BA extending from the first non-display area NA1, and a second non-display area NA2 extending from the bending area BA.

In the first non-display area NA1, a gate driver GD and a plurality of pads PAD may be disposed. The plurality of pads PAD includes pads which are connected to various link lines and a flexible film or a printed circuit board.

The plurality of pads PAD may include a plurality of first pads PAD1, a plurality of second pads PAD2, and a plurality of third pads PAD3. The plurality of first pads PAD1 is located on both sides of the display panel PN in the second non-display area NA2 and the plurality of second pads PAD2 is disposed in the middle of the display panel PN in the second non-display area NA2. For example, the plurality of second pads PAD2 may be located between the plurality of first pads PAD1 and the plurality of third pads PAD3 may be located between the plurality of second pads PAD2.

The plurality of first pads PAD1 is electrically connected to a plurality of gate link lines GLL, among the plurality of link lines LNK. The plurality of gate link lines GLL may be link lines which are connected to the gate driver GD.

The plurality of second pads PAD2 is electrically connected to a plurality of power link lines VLL, among the plurality of link lines LNK. The plurality of power link lines VLL may be link lines which are connected to the power line disposed in the display area AA.

The plurality of third pads PAD3 is electrically connected to a plurality of data link lines DLL, among the plurality of link lines LNK. The plurality of data link lines DLL may be link lines which are connected to the data line disposed in the display area AA.

The gate driver GD supplies a plurality of scan signals to a plurality of scan lines SL according to a plurality of gate control signals supplied from the timing controller. Even though in FIG. 1, it is illustrated that one gate driver GD is disposed to be spaced apart from one side of the display panel PN, the number of the gate drivers GD and the placement thereof are not limited thereto.

The first non-display area NA1 is an area which surrounds the bending area BA and the display area AA and the plurality of link lines LNK, such as the gate link line GLL, the power link line VLL, and the data link line DLL, may be disposed. That is, it serves to transmit a signal transmitted from the plurality of pads PAD to the display area AA. When the display panel PN includes heterogeneous corner areas, the first non-display area NA1 may have a shape corresponding to the shape of the display panel PN and the display area AA.

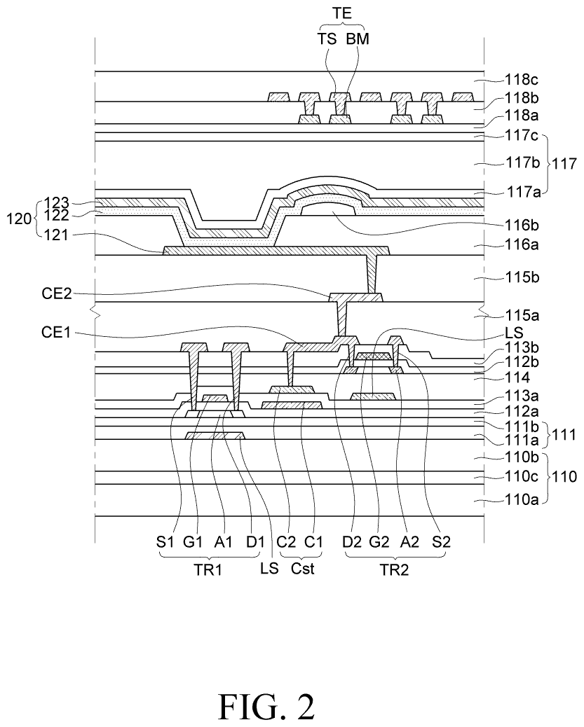

Hereinafter, a cross-sectional structure of the display area AA of the display device 100 will be described in more detail with reference to FIG. 2 together.

FIG. 2 is a cross-sectional view illustrating one sub pixel of a display device according to an exemplary embodiment of the present disclosure.

Referring to FIG. 2, the display device 100 according to an exemplary embodiment of the present disclosure may include a substrate 110, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a first connection electrode CE1, a light shielding layer LS, a first planarization layer 115a, a second planarization layer 115b, a second connection electrode CE2, a bank layer 116a, a spacer 116b, a light emitting diode 120, an encapsulation unit 117, and a touch sensing unit.

The substrate 110 serves to support and protect components of the display device 100 disposed thereabove.

The substrate 110 is a component for supporting various components included in the display device 100 and may be formed of an insulating material. The substrate 110 may include a first substrate 110a, a second substrate 110b, and an interlayer insulating film 110c. The interlayer insulating film 110c may be disposed between the first substrate 110a and the second substrate 110b. As described above, the substrate 110 is configured by the first substrate 110a, the second substrate 110b, and the interlayer insulating film 110c to suppress the moisture permeation. For example, the first substrate 110a and the second substrate 110b may be polyimide (PI) substrates and the interlayer insulating film 110c may be formed of a single layer of silicon nitride (SiNx) or silicon oxide (SiOx) or multiple layers thereof.

The interlayer insulating film 110c may include at least one patterning area. For example, the interlayer insulating film 110c may include an opening portion in the bending area BA.

The first buffer layer 111 is disposed on the substrate 110. The first buffer layer 111 is disposed below the first transistor TR1 to delay diffusion of moisture or oxygen which has permeated into the substrate 110, to the first transistor TR1.

The first buffer layer 111 may include a multi-buffer layer 111a and an active buffer layer 111b. The first buffer layer 111 may include a multiple layer including the multi-buffer layer 111a and the active buffer layer 111b. Therefore, even though the first buffer layer 111 is referred to as a multi-buffer layer, the first buffer layer 111 may be formed by a single layer or may be formed of another number of a plurality of layers, other than two layers, but is not limited thereto.

For example, the multi-buffer layer 111a may be formed by a single layer of any one of amorphous silicon (a-Si), silicon nitride (SiNx), and silicon oxide (SiOx) or a multiple layer thereof, but is not limited thereto.

For example, the active buffer layer 111b may be formed by a single layer of any one of amorphous silicon (a-Si), silicon nitride (SiNx), and silicon oxide (SiOx) or a multiple layer thereof, but is not limited thereto.

The first thin film transistor TR1 may be disposed on the first buffer layer 111. The first thin film transistor TR1 may include a first active layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first active layer A1 may be disposed on the first buffer layer 111 so as to overlap the light shielding layer LS. The first active layer A1 may include amorphous silicon or polycrystalline silicon.

For example, the first active layer A1 may include a low-temperature polycrystalline silicon LTPS. For example, the polycrystalline silicon material has a high mobility (100 cm²/Vs or higher) so that energy power consumption is low and reliability is excellent. Therefore, the polycrystalline silicon material may be applied to a gate driver for driving elements which drive thin film transistors for a display element and/or a multiplexer (MUX) and also applied as an active layer A1 of a driving thin film transistor of the display device 100 according to the exemplary embodiment, but is not limited thereto.

For example, the polycrystalline silicon material may also be applied as the active layer A2 of the switching thin film transistor according to the characteristic of the display device 100. An amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 may include a first channel region in which a channel is formed when the first thin film transistor Tl is driven and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region may be configured by ion-doping (impurity doping) of the first active layer A1. The first source region and the first drain region may be generated by doping ions into the polycrystalline silicon material and the first channel region may refer to a part in which the ions are not doped, but the polycrystalline silicon material remains.

The first gate insulating layer 112a may be disposed on the first active layer A1. The first gate insulating layer 112a may be configured by a single layer of silicon nitride (SiNx) or silicon oxide (SiOx) or a multilayer thereof. In the first gate insulating layer 112a, a contact hole through which the first source electrode S1 and the first drain electrode D1 of the first thin film transistor TR1 are connected to the first source region and the first drain region of the first active layer A1 of the first thin film transistor TR1, respectively, may be formed.

The first gate electrode G1 of the first thin film transistor TR1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a so as to overlap the first channel region of the first active layer A1 of the first thin film transistor TR1.

The first capacitor electrode C1 may be omitted based on a driving characteristic of the display device 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride SiNx or silicon oxide SiOx or a multilayer thereof. In the first insulating layer 113a, a contact hole for exposing the first source region and the first drain region of the first active layer A1 of the first thin film transistor TR1 may be formed.

A second capacitor electrode C2 of the storage capacitor Cst may be disposed on the first interlayer insulating layer 113a. The second capacitor electrode C2 may be formed by a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the thin film transistor.

The second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof. A contact hole for exposing the first source region and the first drain region of the first active layer A1 of the first thin film transistor TR1 may be formed in the second buffer layer 114. Further, in the second buffer layer 114, a contact hole for exposing the second capacitor electrode C2 of the storage capacitor Cst may be formed.

The second buffer layer 114 may be formed by a multiple layer, but is not limited thereto.

The second active layer A2 of the second thin film transistor TR2 may be disposed on the second buffer layer 114. Here, the second thin film transistor TR2 may include a second active layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second active layer A2 may include a second channel region in which a channel is formed when the second thin film transistor TR2 is driven and a second source region and a second drain region on both sides of the second channel region. The second source region may refer to a part of the second active layer A2 which is connected to the second source electrode S2 and the second drain region may refer to a part of the second active layer A2 which is connected to the second drain electrode D2.

The second active layer A2 may be formed of an oxide semiconductor. The oxide semiconductor material has a larger band gap than a silicon material so that electrons may not jump over the band gap in an off state. Therefore, the oxide semiconductor material has a low off-current. Therefore, the thin film transistor including an active layer which is formed of an oxide semiconductor may be suitable for a switching thin film transistor which maintains on-time to be short and off-time to be long, but is not limited thereto. Depending on the characteristic of the display device 100, it may be applied as a driving thin film transistor. Further, due to the small off-current, a magnitude of an auxiliary capacitance may be reduced so that the oxide semiconductor may be appropriate for a high resolution display element. For example, the second active layer A2 may be formed of metal oxide and for example, may be formed of various metal oxide such as indium-gallium-zinc-oxide (IGZO). Here, the description was made under assumption that the second active layer 2 of the second thin film transistor TR2 is configured by IGZO, among various metal oxides, but it is not limited thereto. Therefore, the second active layer may be formed of another metal oxide such as indium-zinc-oxide (IZO), indium-gallium-tin-oxide (IGTO), or indium-gallium-oxide (IGO), rather than IGZO.

The second active layer A2 may be formed by depositing the metal oxide on the second buffer layer 114, performing a heat treatment for stabilization, and then patterning the metal oxide.

The second gate insulating layer 112b may be disposed on the entire substrate 110 including the second active layer A2. For example, the second gate insulating layer 112b may be configured by a single layer of silicon nitride (SiNx) or silicon oxide (SiOx) or a multilayer thereof.

The second gate electrode G2 may be disposed on the second gate insulating layer 112b.

The second gate electrode 134 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b may be disposed on the second gate insulating layer 112b and the second gate electrode G2. A contact hole for exposing the first active layer A1 of the first thin film transistor TR1 and the second active layer A2 of the second thin film transistor TR2 may be formed in the second interlayer insulating layer 113b. For example, a contact hole for exposing the first source region and the first drain region of the first active layer A1 of the first thin film transistor TR1 may be formed in the second interlayer insulating layer 113b. A contact hole for exposing the second source region and the second drain region of the second active layer A2 of the second thin film transistor TR2 may be formed in the second interlayer insulating layer 113b.

The second interlayer insulating layer 113b may be configured as a single layer of silicon nitride (SiNx) or silicon oxide (SiOx) or a multi-layer thereof.

A first connection electrode CE1, the first source electrode S1 and the first drain electrode D1 of the first thin film transistor TR1 and the second source electrode S2 and the second drain electrode D2 of the second thin film transistor TR2 may be disposed on the second interlayer insulating layer 113b.

The first connection electrode CE1 may be electrically connected to the second drain electrode D2 of the second thin film transistor TR2. Further, the first connection electrode CE1 may be electrically connected to the second capacitor electrode C2 of the storage capacitor Cst through the contact holes formed in the second buffer layer 114 and the second interlayer insulating layer 113b. That is, the first connection electrode CE1 may serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 may be connected to the first active layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second active layer A2 through the contact hole formed in the second interlayer insulating layer 113b.

The first connection electrode CE1, the first source electrode S1 and the first drain electrode D1 of the first thin film transistor TR1 and the second source electrode S2 and the second drain electrode D2 of the second thin film transistor TR2 may be formed of the same material by the same process.

For example, the first connection electrode CE1, the first source electrode S1 and the first drain electrode D1 of the first thin film transistor TR1 and the second source electrode S2 and the second drain electrode D2 of the second thin film transistor TR2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the first connection electrode CE1, the first source electrode S1 and the first drain electrode D1 of the first thin film transistor TR1 and the second source electrode S2 and the second drain electrode D2 of the second thin film transistor TR2 may be formed of a triple layered structure of titanium (Ti)/aluminum (Al)/titanium (Ti), but are not limited thereto.

The first connection electrode CE1 may be integrally formed to be connected to the second drain electrode D2 of the second thin film transistor TR2, but is not limited thereto.

In the first transistor TR1 and the second transistor TR2, light shielding layers LS are disposed below the first active layer A1 and the second active layer A2, respectively. The light shielding layer LS is disposed so as to overlap the first active layer A1 between the substrate 110 and the first buffer layer 111 and may be disposed so as to overlap the second active layer A2 between the first interlayer insulating layer 113a and the upper buffer layer 114. Therefore, the light shielding layer LS may be insulated from the first active layer A1 and the second active layer A2.

The light shielding layer LS may be formed of a metal material having low light transmittance and may reflect light which is incident onto the first active layer A1 and the second active layer A2, below the first active layer A1 and the second active layer A2. The light shielding layer LS may shield light which is incident onto the first active layer A1 and the second active layer A2 and may protect the first active layer A1 and the second active layer A2.

For example, the light shielding layer LS may be referred to as a bottom shield metal (BSM), but is not limited thereto. Specifically, the light shielding layer LS may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first planarization layer 115a may be disposed above the first connection electrode CE1, the first source electrode S1 and the first drain electrode D1 of the first thin film transistor TR1 and the second source electrode S2 and the second drain electrode D2 of the second thin film transistor TR2, and the second insulating layer 113b.

The first planarization layer 115a may be an organic layer which planarizes and protects upper portions of the first thin film transistor TR1 and the second thin film transistor TR2. For example, the first planarization layer 115a may be formed of an organic material such as acryl resin, epoxy resin, phenolic resin, polyamide resin, or polyimide resin.

The second connection electrode CE2 may be disposed on the first planarization layer 115a. The second connection electrode CE2 may be connected to the second drain electrode D2 of the second thin film transistor TR2 through the contact hole of the first planarization layer 115a. The second connection electrode CE2 may serve to electrically connect the second thin film transistor TR2 and the first electrode 121 with each other. The second connection electrode CE2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second planarization layer 115b may be disposed above the second connection electrode CE2 and the first planarization layer 115a. For example, the second planarization layer 115b may be formed of an organic material, such as acryl resin, epoxy resin, phenolic resin, polyamide resin, or polyimide resin.

The light emitting diode 120 may be disposed on the second planarization layer 115b. That is, the light emitting diode 120 may be formed by the anode 121, the emission layer 122, and the cathode 123.

The anode 121 may be disposed on the second planarization layer 115b. At this time, the anode 121 may be electrically connected to the second connection electrode CE2 through the contact hole provided in the second planarization layer 115b. The anode 121 may be formed of a metallic material.

When the display device 100 is a top emission type in which light emitted from the light emitting diode 120 is emitted above the substrate 110 in which the light emitting diode 120, the anode 121 may further include a transparent conductive layer and a reflective layer on the transparent conductor layer. The transparent conductive layer may be formed of transparent conductive oxide such as ITO or IZO and the reflective layer may be formed of silver (Ag), aluminum (Al), gold (Au), molybdenum (Mo), tungsten (W), chrome (Cr), or an alloy thereof.

The bank layer 116a may be disposed while covering the anode 121. A part of the bank layer 116a corresponding to an emission area of the sub pixel may be open. A part of the anode 121 may be exposed through the open part of the bank layer 116a (hereinafter, referred to as an open area). At this time, the bank layer 116a may be formed of an inorganic insulating material, such as silicon nitride (SiNx) or silicon oxide (SiOx), or an organic insulating material, such as benzocyclobutene resin, acrylic resin or imide resin, but is not limited thereto. The spacer 116b may be further disposed on the bank layer 116a.

The emission layer 122 may be disposed in the open area of the bank layer 116a and on the front surface thereof. Therefore, the emission layer 122 may be disposed on the anode 121 exposed through the open area of the bank layer 116a.

The emission layer 122 may include a plurality of organic material layers. For example, the emission layer 122 may include an organic material layer such as a hole injection layer, a hole transport layer, an electron transport layer, and an electron injection layer. In the meantime, when the emission layer 122 emits white light, light emitted from the emission layer 122 may be converted into light with various colors by a plurality of color filters, but is not limited thereto.

The cathode 123 may be disposed on the emission layer 122. The cathode 123 supplies electrons to the emission layer 122 so that the cathode may be formed of a conductive material having a low work function. The cathode 123 may be formed as one layer over the plurality of sub pixels SP. That is, the cathodes 123 of the plurality of sub pixels SP are connected to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

The encapsulation unit 117 may be located on the above-described light emitting diode 120.

The encapsulation unit 117 may have a single layer structure or a multi-layered structure. For example, the encapsulation unit 117 may include a first encapsulation layer 117a, a second encapsulation layer 117b, and a third encapsulation layer 117c.

At this time, the first encapsulation layer 117a and the third encapsulation layer 117c may be configured by inorganic layers and the second encapsulation layer 117b may be configured by an organic layer. Among the first encapsulation layer 117a, the second encapsulation layer 117b, and the third encapsulation layer 117c, the second encapsulation layer 117b is the thickest and may serve as a planarization layer.

The first encapsulation layer 117a is disposed on the cathode 123 and may be disposed to be most adjacent to the light emitting diode 120. The first encapsulation layer 117a may be formed of an inorganic insulating material on which low-temperature deposition may be performed. For example, the first encapsulation layer 117a may be configured by silicon nitride (SiNx), silicon oxide (SiOx), silicon oxynitride (SiON), or aluminum oxide (Al₂O₃). The first encapsulation layer 117a is deposited under a low temperature atmosphere so that during the deposition process, the damage of the emission layer 122 including an organic material which is vulnerable to the high temperature atmosphere may be suppressed.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve as a buffer to alleviate stress between the layers due to bending of the display device and to enhance planarization performance.

For example, the second encapsulation layer 117b may be formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

The third encapsulation layer 117c may be formed above the substrate 110 on which the second encapsulation layer 117b may be formed so as to cover upper surfaces and side surfaces of the second encapsulation layer 117b and the first encapsulation layer 117a. At this time, the third encapsulation layer 117c may minimize or block the permeation of external moisture or oxygen into the first encapsulation layer 117a and the second encapsulation layer 117b. For example, the third encapsulation layer 117c may be configured by an inorganic insulating material, such as silicon nitride (SiNx), silicon oxide (SiOx), silicon oxynitride (SiON), or aluminum oxide (Al₂O₃).

The touch sensing unit may be disposed on the encapsulation unit 117. The touch sensing unit may include a touch electrode unit TE including a touch sensor metal TS and a bridge metal BM and a touch insulating layer including a touch buffer layer 118a, a touch interlayer insulating layer 118b, and a touch planarization layer 118c.

For example, the touch buffer layer 118a is disposed on the third encapsulation layer 117c and the touch electrode unit TE may be disposed on the touch buffer layer 118a.

The touch electrode unit TE may include a touch sensor metal TS and a bridge metal BM located on different layers. A touch interlayer insulating layer 118b may be disposed between the touch sensor metal TS and the bridge metal BM.

The touch buffer layer 118a and the touch interlayer insulating layer 118b may be disposed to remove a step of a location where the touch electrode unit TE is disposed and be electrically insulated. Therefore, the touch buffer layer 118a and the touch interlayer insulating layer 118b may be formed of an inorganic material, and for example, may be configured by a single layer or a multiple layer of silicon nitride (SiNx) or silicon oxide (SiOx).

The touch planarization layer 118c is disposed on the touch interlayer insulating layer 118b and the touch sensor metal TS. The touch planarization layer 118c may be an organic layer which planarizes and protects an upper portion of the touch interlayer insulating layer 118b. For example, the touch planarization layer 118c may be formed of an organic material such as acryl resin, epoxy resin, phenolic resin, polyamide resin, or polyimide resin. The touch electrode unit TE may be formed as a mesh type.

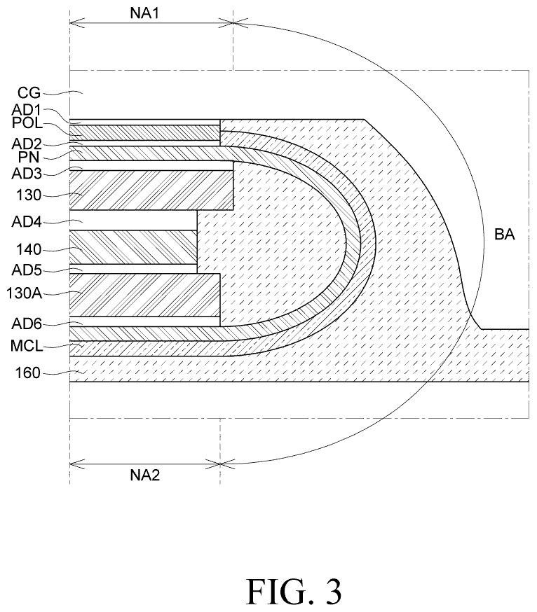

FIG. 3 is a cross-sectional view illustrating a bent state of a display device according to an exemplary embodiment of the present disclosure. In the meantime, in FIG. 3, for the convenience of description, among components of the display device 100, only the display panel PN, a first adhesive layer AD1, a second adhesive layer AD2, a polarizer POL, a cover window 120, a third adhesive layer AD3, a fourth adhesive layer AD4, a fifth adhesive layer AD5, a sixth adhesive layer AD6, a back plate 130, a support plate 140, an additional back plate 130A, a micro coating layer MCL, and a molding member 160 are illustrated.

Referring to FIGS. 1 and 3, the display device 100 according to the exemplary embodiment of the present disclosure may include the first adhesive layer AD1, the second adhesive layer AD2, the polarizer POL, the cover window CG, the micro coating layer MCL, and the molding member 160 which are disposed on the display panel PN and the third adhesive layer AD3, the fourth adhesive layer AD4, the fifth adhesive layer AD5, the sixth adhesive layer AD6, the back plate 130, the support plate 140, and the additional back plate 130A disposed below the display panel PN.

Referring to FIG. 3, the cover window CG is disposed on the front surface of the display panel PN. The cover window CG may be a component which is exposed to the outer periphery of the display device 100 and protect the display device 100 from external shock or scratches. Further, the cover window CG may protect the display device 100 from moisture permeating from the outside. The cover window CG may be formed of a glass or a plastic material having a flexibility, but is not limited thereto.

The polarizer POL is disposed between the display panel PN and the cover window CG. The polarizer POL may be disposed on the front surface of the display panel PN. That is, the polarizer POL may be disposed on the touch electrode unit TE of the display panel PN. The polarizer POL selectively transmits light to reduce the reflection of external light which is incident onto the display panel PN. Specifically, the display panel PN includes various metal materials applied to the semiconductor element, the wiring line, and the organic light emitting diode. Therefore, the external light incident onto the display panel PN may be reflected from the metal material so that the visibility of the display device 100 may be reduced due to the reflection of the external light. In contrast, when the polarizer POL is disposed, the polarizer POL suppresses the reflection of the external light so that the outdoor visibility of the display device 100 may be increased. However, the polarizer POL may be omitted depending on an implementation example of the display device 100, but it is not limited thereto.

The first adhesive layer AD1 is disposed between the polarizer POL and the cover window CG and the second adhesive layer AD2 is disposed between the polarizer POL and the display panel PN. The first adhesive layer AD1 may bond the cover window CG and the polarizer POL and the second adhesive layer AD2 may bond the polarizer POL and the display panel PN. As a result, the first adhesive layer AD1 and the second adhesive layer AD2 may bond the display panel PN and the cover window CG. The first adhesive layer AD1 and the second adhesive layer AD2 may be formed as transparent adhesive layers so that an image of the display panel PN may be visible. For example, the first adhesive layer AD1 and the second adhesive layer AD2 may be formed of an optical clear adhesive (OCA) or a pressure sensitive adhesive (PSA), but are not limited thereto.

The back plate 130 is disposed below the display panel PN. The back plate 130 may be disposed so as to support the display panel PN. For example, when the substrate 110 of the display panel PN is formed of a plastic material, such as polyimide, due to the flexible property, a separate component for supporting the substrate may be necessary. Therefore, a support substrate which is formed of glass is disposed below the substrate 110 to perform a manufacturing process of the display device 100 and the support substrate may be separated to be released after completing the manufacturing process. However, a component for supporting the substrate 110 is necessary even after releasing the support substrate, so that a back plate 130 for supporting the substrate 110 may be disposed below the display panel PN.

The back plate 130 may include a plastic material. For example, the back plate 130 may be formed of a plastic thin film formed of polyimide (PI), polyethylene naphthalate (PEN), polyethylene terephthalate (PET), or a combination of the polymers.

The third adhesive layer AD3 is disposed between the display panel PN and the back plate 130. The third adhesive layer AD3 may bond the display panel PN and the back plate 130. The third adhesive layer AD3 may be formed of an optical clear adhesive (OCA) or a pressure sensitive adhesive (PSA), but is not limited thereto.

The support plate 140 is disposed below the back plate 130. The metal plate 140 may protect the components of the display device 100 from external shocks. Further, the support plate 140 serves as an earth to suppress the static electricity penetrating the display device 100 or easily discharge residual charges accumulated in the display device 100 to the outside. Further, the support plate 140 may easily discharge heat generated in the display device 100 to the outside. The support plate 140 may be formed of a metal material having excellent thermal conductivity, electrical conductivity, and mechanical rigidity. For example, the support plate 140 may be configured by copper (Cu) or stainless steel (SUS), but is not limited thereto.

The fourth adhesive layer AD4 is disposed between the back plate 130 and the support plate 140. The fourth adhesive layer AD4 may bond the back plate 130 and the support plate 140 to each other. The fourth adhesive layer AD4 may be formed of an optical clear adhesive (OCA) or a pressure sensitive adhesive (PSA), but is not limited thereto.

The additional back plate 130A is disposed below the support plate 140 corresponding to the first non-display area NA1.

The additional back plate 130A may supplement the rigidity of the second non-display area NA2 of the display panel PN disposed in the second non-display area NA2. In the meantime, the additional back plate 130A may be disposed so as not to overlap the bending area BA. Therefore, the thicknesses of the configurations disposed in the bending area BA may be minimized and a neutral plane of the bending area BA is easily controlled to ensure the flexibility of the bending area.

The fifth adhesive layer AD5 is disposed between the support plate 140 and the additional metal plate 140A. The fifth adhesive layer AD5 may bond the metal plate 140 and the additional back plate 130A. For example, the fifth adhesive layer AD5 may be formed of an optical clear adhesive (OCA) or a pressure sensitive adhesive (PSA), but is not limited thereto.

The second non-display area NA2 of the display panel PN is disposed below the additional back plate 130A. The sixth adhesive layer AD6 is disposed between the additional back plate 130A and the second non-display area NA2 of the display panel PN. The sixth adhesive layer AD6 may bond between the additional back plate 130A and the second non-display area NA2 of the display panel PN. For example, the sixth adhesive layer AD6 may be formed of an optical clear adhesive (OCA) or a pressure sensitive adhesive (PSA), but is not limited thereto.

The micro coating layer MCL is disposed on the first non-display area NA1, the second non-display area NA2, and the bending area BA of the display panel PN. Since a tensile force is applied to a plurality of link lines LNK disposed on the substrate 110 at the time of bending to cause minute crack, the micro coating layer MCL may be formed by coating a resin in a position to be bent with a small thickness to protect the plurality of link lines LNK.

The plurality of link lines LNK may be disposed on the same layer in the bending area BA. For example, the plurality of link lines LNK may be formed on the same layer as the second connection electrode CE2 illustrated in FIG. 2 in the bending area BA.

The micro coating layer MCL may be configured by resin or configured by an acrylic material or urethane acrylate, but is not limited thereto.

The molding member 160 seals the cover window CG, the polarizer POL, the display panel PN, the back plate 130, the support plate 140, and the additional back plate 130A. Specifically, the molding member 140 may be disposed so as to enclose a bottom of the cover window CG, a bottom surface of the display panel PN, a side surface of the back plate 130, a side surface of the support plate 140, a side surface of the additional back plate 130A, and a top surface of the micro coating layer MCL. The molding member 160 may suppress the permeation of the moisture or oxygen into the display device 100. Further, the molding member 160 may protect components of the display device 100 and may relieve shocks applied to the display device 100.

For example, the molding member 160 may be formed by a process of removing a mold, after filling and curing a mold which is disposed to enclose a side surface of the cover window CG and expose a bottom surface of the display panel PN, a side surface of the back plate 130, a side surface of the support plate 140, a side surface of the frame 150, and a part of a bottom surface of the frame 150 with a material for forming the molding member 160. However, the method of forming the molding member 160 is not limited thereto.

The molding member 160 may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

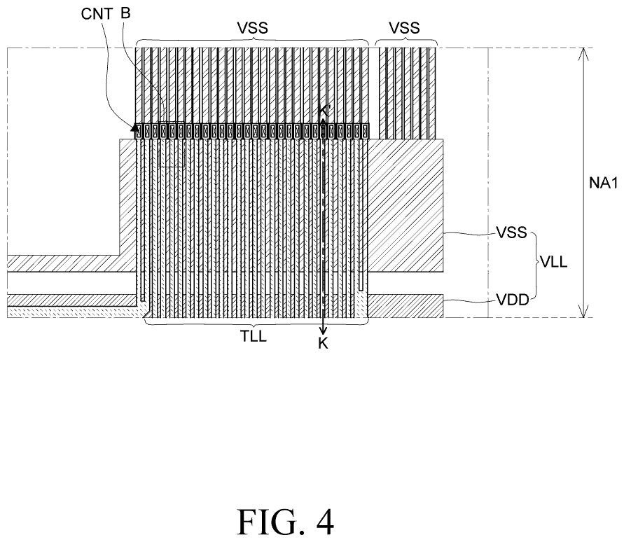

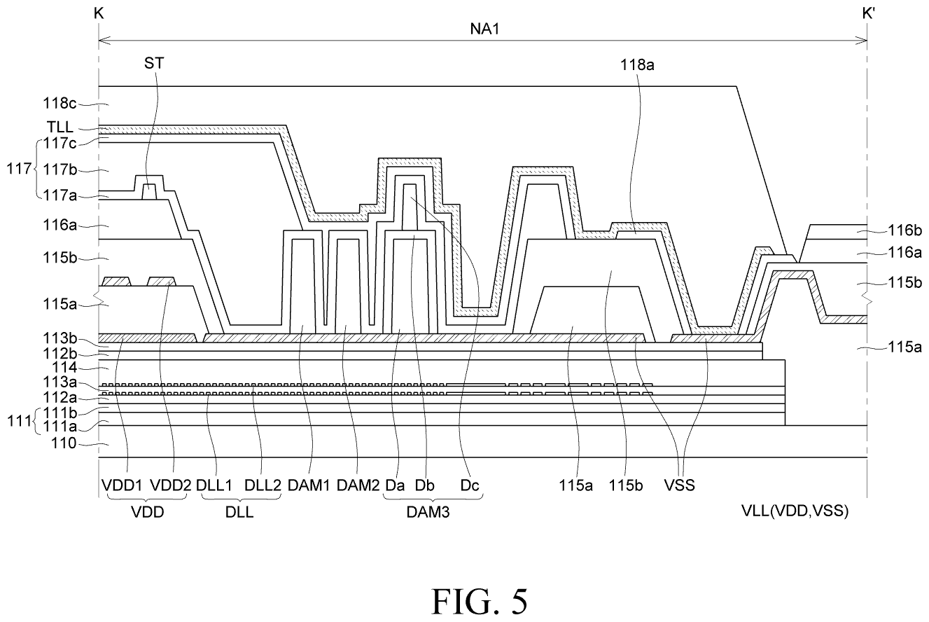

FIG. 4 is an enlarged plan view of an area A of FIG. 1 and FIG. 5 is a cross-sectional view taken along V-V′ of FIG. 4. For the convenience of description, in FIG. 4, among various components of the display device 100, only a plurality of power link lines VLL and a plurality of touch link lines TLL are illustrated. In FIG. 5, only a substrate 110, a multi-buffer layer 111a, an active buffer layer 111b, a first gate insulating layer 112a, a first interlayer insulating layer 113a, a second buffer layer 114, a second gate insulating layer 112b, a second interlayer insulating layer 113b, a plurality of data link lines DLL1 and DLL2, a first planarization layer 115a, a second planarization layer 115b, a plurality of power link lines VLL, a bank layer 116a, a stopper ST, a first encapsulation layer 117a, a second encapsulation layer 117b, a third encapsulation layer 117c, a touch buffer layer 118a, a plurality of touch link lines TLL, and a touch planarization layer 118c are illustrated.

Referring to FIGS. 1 and 4, the plurality of link lines LNK may include a plurality of gate link lines GLL, a plurality of power link lines VLL, and a plurality of data link lines DLL in both outer peripheral areas of the display area AA of the first non-display area NA1. Here, the gate link line GLL is connected to a gate line and the data link line DLL is connected to a data line of the display area AA, but are omitted for the convenience of description.

The plurality of power link lines VLL may connect the plurality of pads PAD and various wiring lines of the display area AA. Specifically, the plurality of power link lines VLL may transmit a signal for driving a pixel of the display area AA from the plurality of second pads PAD2 to various wiring lines. For example, the power link line VLL may transmit the high potential power voltage and the low potential power voltage to the display area AA.

The plurality of power link lines VLL may include a low potential power link line VSS and a high potential power link line VDD.

The low potential power link line VSS may be disposed in the first non-display area NA1, the bending area BA, and the second non-display area NA2. The low potential power link line VSS may electrically connect the low potential power line disposed in the display area and the second pad unit PAD2 corresponding thereto. The low potential power link line VSS may extend from the low potential power line. The low potential power link line VSS may be integrally formed with the low potential power line. That is, the low potential power link line VSS may be formed of the same material as the low potential power line.

The high potential power link line VDD may be disposed in the first non-display area NA1, the bending area BA, and the second non-display area NA2. The high potential power link line VDD may electrically connect the high potential power line disposed in the display area and the second pad PAD2 corresponding thereto. The high potential power link line VDD may extend from the high potential power line. The high potential power link line VDD may be integrally formed with the high potential power line. That is, the high potential power link line VDD may be formed of the same material as the high potential power line.

The plurality of touch link lines TLL may be connected to the touch electrode unit TE disposed in the display area AA. Specifically, the plurality of touch link lines TLL may transmit a signal for sensing a touch of the display area AA from the plurality of second pads PAD2 to the touch electrode unit and may transmit a signal sensed from the touch electrode unit to the plurality of second pads.

Further, the plurality of touch link lines TLL may include a low potential touch link line. The low potential touch link line of the touch link line may be applied with a low potential power voltage to block a nose to another touch link line or the touch electrode unit TE. The plurality of touch link lines TLL illustrated in FIGS. 4 and 5 is a view for a low potential touch link line and it is assumed that the plurality of touch link lines TLL which will be described below is a low potential touch link line.

Referring to FIG. 5, on the substrate 110, the multi-buffer layer 111a, the active buffer layer 111b, and the first gate insulating layer 112a are disposed and on the multi-buffer layer 111a, the active buffer layer 111b, and the first gate insulating layer 112a, the plurality of first data link lines DLL1 is disposed. The plurality of first data link lines DLL1 may be connected to the data line.

The plurality of first data link lines DLL1 is disposed on the multi-buffer layer 111a, the active buffer layer 111b, and the first gate insulating layer 112a to be formed of the same layer as the first gate electrode G1 with the same material, but is not limited thereto.

The first interlayer insulating layer 113a is disposed on the plurality of data link lines DLL1 and the plurality of second data link lines DLL2 is disposed on the first interlayer insulating layer 113a. The plurality of second data link lines DLL2 is simultaneously formed on the same layer as the second capacitor electrode C2 to be formed of the same material, but is not limited thereto.

The first high potential power link line VDD1 is disposed on the plurality of second data link lines DLL2, the first interlayer insulating layer 113a, the second gate insulating layer 112b, the second buffer layer 114, and the second interlayer insulating layer 113b.

The first high potential power link line VDD1 is simultaneously formed on the same layer as the first source electrode S1, the first drain electrode D1, the second source electrode S2, and the second drain electrode D2 to be formed of the same material, but is not limited thereto.

The first planarization layer 115a is disposed on the first high potential power link line VDD1 and the second high potential power link line VDD2 is disposed on the first planarization layer 115a. The second high potential power link line VDD2 is simultaneously formed on the same layer as the second connection electrode CE2 to be formed of the same material, but is not limited thereto.

The low potential power link line VSS is disposed on the second interlayer insulating layer 113b. The low potential power link line VSS may be disposed on the same layer as the first high potential power link line VDD1. The low potential power link line VSS may be electrically connected to the plurality of touch link lines TLL through a contact hole of the second planarization layer 115b at the outermost side of the first non-display area NA1.

The second planarization layer 115b, the bank layer 116a, the touch buffer layer 118a, and the touch planarization layer 118c may be disposed on the second high potential power link line VDD2.

The stopper ST is disposed on the bank layer 116a. The stopper ST is disposed on the bank layer 116b in the first non-display area NA1. The stopper ST may suppress the second encapsulation layer 116b which is a part of the encapsulation unit 117 in the first non-display area NA1 from overflowing to the bending area BA. That is, the stopper ST is a primary structure which suppresses the second encapsulation layer 117b of the encapsulation unit 117 which protects the light emitting diode 120 from invading or being leaked to the bending area BA. For example, the stopper ST is simultaneously formed on the same layer as the spacer 116b to be formed of the same material, but is not limited thereto.

The plurality of touch link lines TLL is disposed between the touch buffer layer 118a and the touch planarization layer 118c. That is, the touch planarization layer 118c may be disposed on the touch electrode unit TE and the plurality of touch link lines TLL. The plurality of touch link lines TLL may be electrically connected to the plurality of power link lines VLL through a plurality of contact holes CNT of the second planarization layer 115b in the first non-display area NA1. That is, the plurality of touch link lines TLL is connected to the plurality of low potential power link lines VSS at the outside of the second planarization layer 115b to transmits a low potential power which is a constant voltage.

In the first non-display area NA1, a plurality of dams DAM1, DAM2, and DAM3 may be disposed. The plurality of dams DAM1, DAM2, and DAM3 may include a first dam DAM1, a second dam DAM2, and a third dam DAM3. For example, in the first non-display area NA1, the first dam DAM1 is disposed to be closer to the display aera AA than the second dam DAM2. The second dam DAM2 is disposed to be closer to the display area AA than the third dam DAM3. The third dam DAM3 is disposed to be closer to the outside, that is, toward the bending area BA, than the first dam DAM1 and the second dam DAM2. The second dam DAM2 may be disposed between the first dam DAM1 and the third dam DAM3.

The first dam DAM1, the second dam DAM2, and the third dam DAM3 may secondarily block the flow of the second encapsulation layer 117b which configures the encapsulation unit 117. The plurality of dams DAM1, DAM2, and DAM3 needs to be formed to have a predetermined height or higher to block the flow of the second encapsulation layer 117b. To this end, the plurality of dams DAM1, DAM2, and DAM3 may be formed of at least one or more layers formed of an organic material.

For example, the first dam DAM1 and the second dam DAM2 may be formed with a single layered structure formed of the same material as the second planarization layer 115a. The third dam DAM3 may be formed with a multi-layered structure including a first layer Da formed of the same material as the second planarization layer 115b, a second layer Db formed of the same material as the bank layer 116a on the first layer Da, and a third layer De formed of the same material as the stopper ST on the second layer Db. However, the present disclosure is not limited thereto.

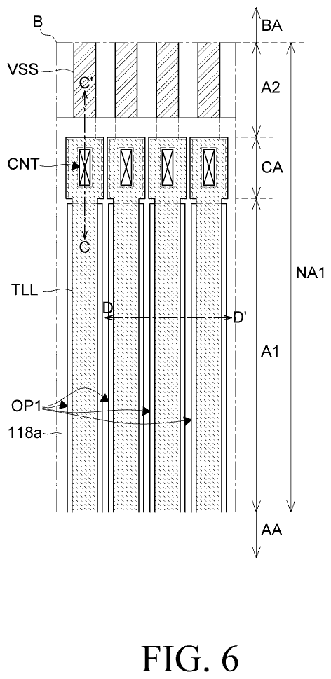

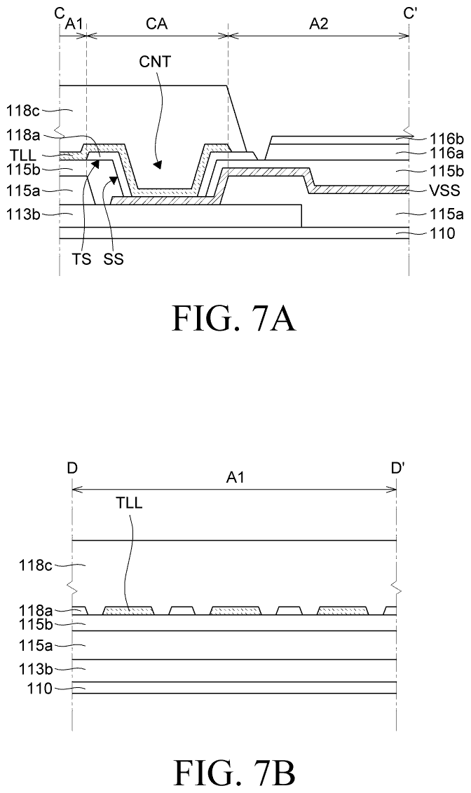

Hereinafter, an area where the plurality of touch link lines TLL and the low potential power link line VSS among the plurality of power link lines VLL are electrically connected at the outermost side of the first non-display area NA1 will be described in more detail with reference to FIGS. 6, 7A, and 7B together.

FIG. 6 is an enlarged plan view of an area B of FIG. 4. FIG. 7A is a cross-sectional view taken along C-C′ of FIG. 6. FIG. 7B is a cross-sectional view taken along D-D′ of FIG. 6. In FIG. 6, only a touch buffer layer 118a, a low potential power link line VSS, and a plurality of touch link lines TLL are illustrated for the convenience of description. In FIGS. 7A and 7B, for the convenience of description, only a substrate 110, a second interlayer insulating layer 113b, a first planarization layer 115a, a second planarization layer 115b, a bank layer 116a, a spacer 116b, a touch buffer layer 118a, and a touch planarization layer 118c are illustrated.

Referring to FIGS. 6 and 7A, the first non-display area NA1 may include a first area A1, a contact area CA, and a second area A2 between a display area and a bending area. Here, the contact area CA may be defined as an area in which the plurality of touch link lines TLL and a low potential power link line VSS, among the plurality of power link lines VLL are electrically connected in a plurality of contact holes CNT of the second planarization layer 115b. The first area A1 may be defined as the first non-display area NA1 closer to the display area AA than the plurality of contact holes CNT with respect to the contact area CA. The second area A2 may be defined as the first non-display area NA1 closer to the bending area BA than the plurality of contact holes CNT with respect to the contact area CA.

In the first non-display area NA1, the second interlayer insulating layer 113b is disposed on the substrate 110.

The first planarization layer 115a and the second planarization layer 115b are disposed on the substrate 110 and the second interlayer insulating layer 113b. Specifically, the power link line VSS is disposed on the second interlayer insulating layer 113b and the first planarization layer 115a. The second planarization layer 115b is disposed on the low potential power link line VSS. In the second area A2, the bank layer 116a and the spacer 116b are disposed on the second planarization layer 115b.

The touch buffer layer 118a is disposed on the second planarization layer 115b in the first area A1. The touch buffer layer 118a includes a plurality of openings OP1 in the first area A1. That is, the touch buffer layer 118a may include a plurality of openings OP1 in the first area A1 which is a first non-display area NA1 closer to the display area AA than the plurality of contact holes CNT of the second planarization layer 115b.

In the contact area CA, the touch buffer layer 118a is disposed on the side surface SS of the second planarization layer 115b in the plurality of contact holes CNT of the second planarization layer 115b and may be disposed in a part of a top surface of the second planarization layer 115b adjacent to the plurality of contact holes CNT of the second planarization layer 115b. That is, the touch buffer layer 118a may be disposed along a side surface SS of the second planarization layer 115b in the plurality of contact holes CNT to extend to a part of the top surface TS of the second planarization layer 115b. For example, in the contact area CA, the touch buffer layer 118a is disposed between the second planarization layer 115b and the plurality of touch link lines TLL along a side surface SS of the second planarization layer 115b.

In the contact area CA and the first area A1, the plurality of touch link lines TLL covers an end of the touch buffer layer 118a and is in contact with the second planarization layer 115b. Further, the plurality of touch link lines TLL is disposed so as not to be in contact with an end of the touch buffer layer 118a in a part extending from the contact area CA to the second area A2.

In the meantime, in the first non-display area NA1, the touch planarization layer 118c may be disposed on the plurality of touch link lines TLL and an end of the touch planarization layer 118c may be disposed on the touch buffer layer 118a. That is, the end of the touch planarization layer 118c may be disposed so as not to be in contact with the end of the touch buffer layer 118a. Further, in the second area A2, the end of the touch planarization layer 118c may be spaced apart from the bank layer 116a.

Referring to FIGS. 6 and 7B, in the first non-display area NA1, the touch buffer layer 118a may be disposed on the second planarization layer 115b in an area between the plurality of touch link lines TLL.

The plurality of touch link lines TLL is disposed on the second planarization layer 115b in the first area A1. The plurality of touch link lines TLL may be disposed in a plurality of openings OP1 in the first area A1. Therefore, in the first area A1, the plurality of touch link lines TLL and the touch buffer layer 118a may be disposed on the same plane on the second planarization layer 115b. For example, the plurality of touch link lines TLL and the touch buffer layer 118a may be alternately disposed on the second planarization layer 115b.

The touch planarization layer 118c may be disposed on the plurality of touch link lines TLL in the first area A1.

In the case of the low potential touch link line, among the touch link lines in the display device, the low potential power voltage used for the display device may be commonly used. Accordingly, in the non-display area adjacent to the bending area, the touch link line and the low potential power link line may be in contact with each other. Therefore, for the contact of the touch link line and the low potential power link line, a contact hole is formed on the planarization layer above the power link line to achieve electrical connection. At this time, the touch buffer layer may be disposed between the touch link line and the planarization layer. In the meantime, in the display device, a molding member which seals the components of the display device is disposed below the cover window to minimize the size of the bezel area.

However, when a process of heating and cooling the display device is repeated, the components of the display panel of the display device expand and contract and the molding member also expands and contracts. When this process is repeated, the components of the display device may be pressurized. At this time, the adhesion of the touch buffer layer may be weakened at the interface between the touch buffer layer in the bending area side and the bank layer. Therefore, the film lifting of the touch buffer layer may be caused and the plurality of touch link lines on the touch buffer layer is also lifted together with the touch buffer layer so that the plurality of touch link lines is cracked. By doing this, there may be a problem in that the touch electrode unit does not normally operate.

Accordingly, in the display device 100 according to the exemplary embodiment of the present disclosure, in the first area A1, the plurality of touch link lines TLL and the touch buffer layer 118a are disposed on the same plane on the second planarization layer 115b to improve the erroneous operation of the touch electrode unit TE. Specifically, in the first area A1 which is the first non-display area NA1 which is closer to the display area AA than the plurality of contact holes CNT of the second planarization layer 115b, the plurality of touch link lines TLL and the touch buffer layer 118a may be alternately disposed on the same plane on the second planarization layer 115b. Accordingly, a contact area of the touch buffer layer 118a and the second planarization layer 115b is reduced and the plurality of touch link lines TLL may be disposed on the second planarization layer 115b, rather than the touch buffer layer 118a, in the first area A1. Therefore, the plurality of touch link lines TLL may be in contact with a top surface of the second planarization layer 115b. That is, the plurality of touch link lines TLL and the touch buffer layer 118a are in direct contact with each other on the second planarization layer 115b to suppress the lifting of the plurality of touch link lines TLL together with the touch buffer layer 118a. Accordingly, even though the film lifting is caused in the second area A2, the plurality of touch link lines TLL in the first area A1 passing the contact area CA and the second planarization layer 115b are in direct contact to suppress the crack of the plurality of touch link lines TLL. Accordingly, in the display device 100 according to the exemplary embodiment of the present disclosure, the plurality of touch link lines TLL and the touch buffer layer 118a are disposed on the same plane on the second planarization layer 115b to suppress the crack of the plurality of touch link lines TLL, thereby improving the erroneous operation of the touch electrode unit TE. Further, the defect of the display device 100 may be minimized.

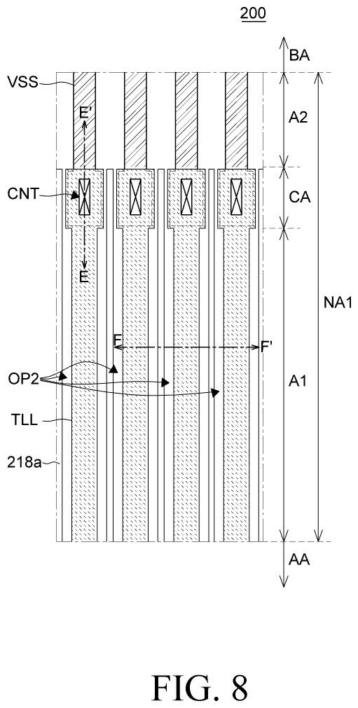

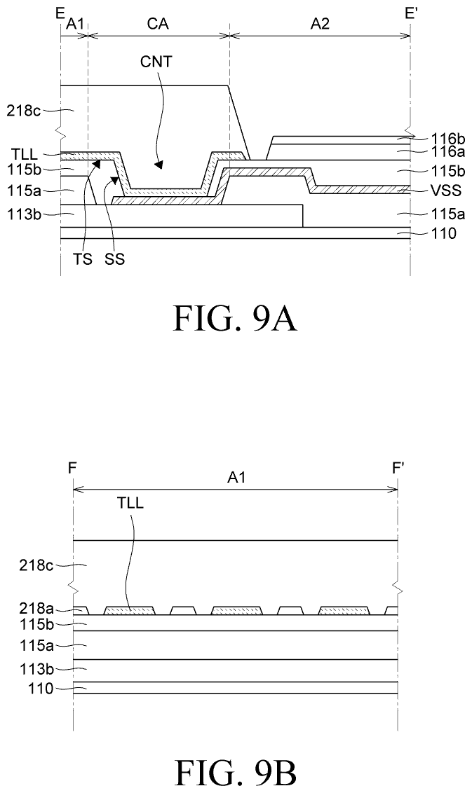

FIG. 8 is a cross-sectional view of a display device according to another exemplary embodiment of the present disclosure. FIG. 9A is a cross-sectional view taken along E-E′ of FIG. 8. FIG. 9B is a cross-sectional view taken along F-F′ of FIG. 8. A display device 200 of FIGS. 8 to 9B has the substantially same components as the display device 100 of FIGS. 1 to 7B except contents for only a plurality of touch link lines TLL, a touch buffer layer 218a, a plurality of openings OP2, and a touch planarization layer 218c are changed. Therefore, a redundant description will be omitted.

Referring to FIG. 8, in the first area A1 and the contact area CA of the first non-display area NA1, the touch buffer layer 218a includes a plurality of openings OP2. That is, the plurality of touch link lines TLL may be disposed in a plurality of openings OP2 in the first area A1 and the contact area CA.

Referring to FIGS. 8 and 9A, in the contact area CA of the first non-display area NA1, the plurality of touch link lines TLL is disposed on the second planarization layer 115b. In the contact area CA, the plurality of touch link lines TLL is disposed to be in contact with a side surface SS of the second planarization layer 115b. That is, the plurality of touch link lines TLL is disposed along the side surface SS of the second planarization layer 115b to extend to a top surface TS of the second planarization layer 115b.

In the first area A1, the contact area CA, and the second area A2, the touch planarization layer 218c may be disposed on the plurality of touch link lines TLL. An end of the touch planarization layer 218c may be disposed on the second planarization layer 115b so as to cover the end of the plurality of touch link lines TLL. In the second area A2, an end of the touch planarization layer 218c may be spaced apart from the bank layer 116a. That is, in the second area A2, an end of the touch planarization layer 218c and an end of the bank layer 116a and the spacer 116b may be spaced apart from each other.

Referring to FIGS. 8 and 9B, in the first non-display area NA1, the touch buffer layer 218a may be disposed on the second planarization layer 115b in an area between the plurality of touch link lines TLL. In the first non-display area NA1, the touch buffer layer 218a may be disposed in an area between the plurality of contact holes CNT of the second planarization layer 115b. That is, the touch buffer layer 218a may be disposed in an area between the plurality of touch link lines TLL in the first area A1 and the contact area CA.

Therefore, in the first area A1 and the contact area CA of the first non-display area NA1, the plurality of touch link lines TLL and the touch buffer layer 218a may be disposed on the same plane on the second planarization layer 115b. For example, the plurality of touch link lines TLL and the touch buffer layer 218a may be alternately disposed on the second planarization layer 115b.

The touch planarization layer 218c may be disposed on the plurality of touch link lines TLL and the touch buffer layer 218a in the first area A1 of the first non-display area NA1.

Accordingly, in the display device 200 according to another exemplary embodiment of the present disclosure, in the first area A1 of the first non-display area NA1, the plurality of touch link lines TLL and the touch buffer layer 218a may be disposed on the same plane on the second planarization layer 115b. Therefore, the erroneous operation of the touch electrode unit TE may be improved.

Further, in the display device 200 according to another exemplary embodiment of the present disclosure, the plurality of touch link lines TLL is disposed to be in direct contact with the second planarization layer 115b in the first non-display area NA1. therefore, the problem in that the plurality of touch link lines TLL is cracked due to the film lifting of the touch buffer layer 218a in the second area A2 may be suppressed in advance. Therefore, in the display device 200 according to another exemplary embodiment of the present disclosure, the damage of the touch electrode unit TE is minimized to improve the lifespan of the display device 200 to be driven at a low power.

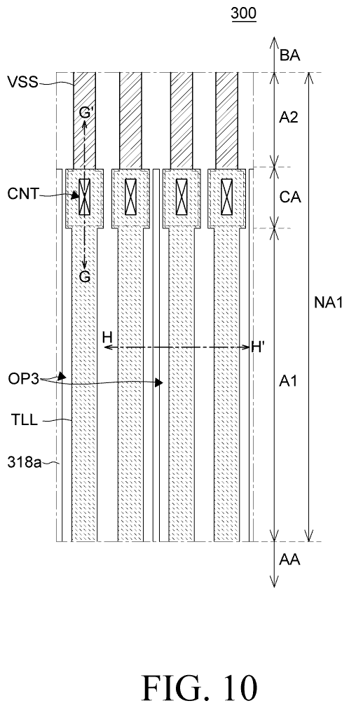

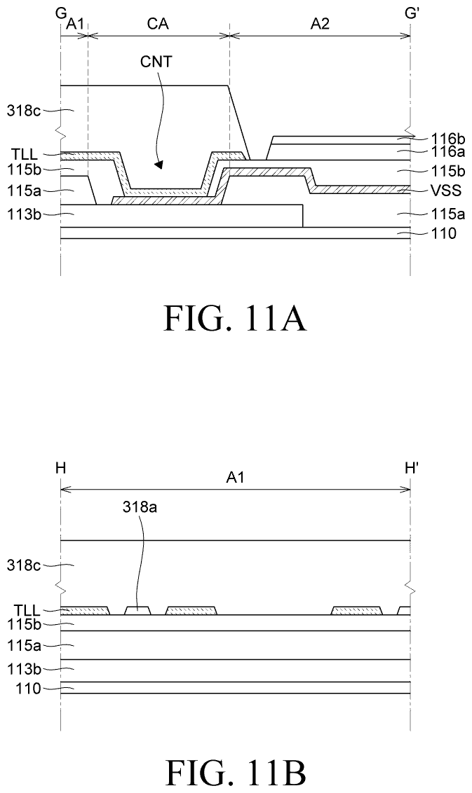

FIG. 10 is a cross-sectional view of a display device according to still another exemplary embodiment of the present disclosure. FIG. 11A is a cross-sectional view taken along G-G′ of FIG. 10. FIG. 11B is a cross-sectional view taken along H-H′ of FIG. 10. A display device 300 of FIGS. 10 to 11B has the substantially same components as the display device 200 of FIGS. 8 to 9B except contents for only a touch buffer layer 318a and a plurality of openings OP3 are changed. Therefore, a redundant description will be omitted. In the meantime, FIG. 11A is the substantially same as FIG. 9A so that a redundant description will be omitted.

Referring to FIG. 10, in the first area A1 and the contact area CA of the first non-display area NA1, the touch buffer layer 318a includes a plurality of openings OP3. That is, the plurality of touch link lines TLL may be disposed in a plurality of openings OP3 in the first area A1 and the contact area CA. For example, the plurality of openings OP3 of the touch buffer layer 318a may have a size to place two touch link lines TLL. Therefore, two touch link lines TLL, among the plurality of touch link lines TLL, may be disposed so as to match one opening OP3, among the plurality of openings OP3, but are not limited thereto.

In the first non-display area NA1, the touch buffer layer 318a may be disposed in a partial area of an area between the plurality of contact holes CNT of the second planarization layer 115b. For example, contact holes CNT of two second planarization layers 115b are defined as one pair and the touch buffer layer 318a may be disposed in an area between one pair of contact holes CNT, but the present disclosure is not limited thereto. In the first non-display area NA1, a ratio of an area of the touch buffer layer 318a disposed on the same plane may be reduced as compared with that of FIG. 8.

Referring to FIGS. 10 and 11B, in the first area A1 of the first non-display area NA1, the touch buffer layer 318a may be disposed on the second planarization layer 115b in a partial area of an area between the plurality of touch link lines TLL. For example, the touch buffer layer 318a may be disposed on the second planarization layer 115b in an area between two touch link lines TLL, in an area between the plurality of touch link lines TLL.

Further, the plurality of touch link lines TLL is disposed on the second planarization layer 115b in the first area A1. The plurality of touch link lines TLL may be disposed in the plurality of openings OP3 in the first area A1. That is, in the first area A1, the plurality of touch link lines TLL and the touch buffer layer 318a may be disposed on the same plane on the second planarization layer 115b. For example, the plurality of touch link lines TLL and the touch buffer layer 318a may be alternately disposed on the second planarization layer 115b. At this time, two touch link lines TLL, among the plurality of touch link lines TLL, and the touch buffer layer 318a may be alternately disposed on the second planarization layer 115b.

The touch planarization layer 318c may be disposed on the plurality of touch link lines TLL and the touch buffer layer 318a in the first area A1 of the first non-display area NA1.

Accordingly, in the display device 300 according to another exemplary embodiment of the present disclosure, in the first non-display area NA1, the plurality of touch link lines TLL and the touch buffer layer 318a are disposed on the same plane on the second planarization layer 115b to reduce the placement area of the touch buffer layer 318a. Therefore, the erroneous operation of the touch electrode unit TE may be improved.

Further, in the display device 300 according to another exemplary embodiment of the present disclosure, the plurality of touch link lines TLL is disposed to be in direct contact with the second planarization layer 115b in the first non-display area NA1, therefore, the problem in that the plurality of touch link lines TLL is cracked due to the film lifting of the touch buffer layer 218a in the second area A2 may be suppressed in advance. By doing this, the display device 300 according to the exemplary embodiment of the present disclosure minimizes the damage of the touch electrode unit TE to improve the lifespan of the display device 300 to be driven at a low power.

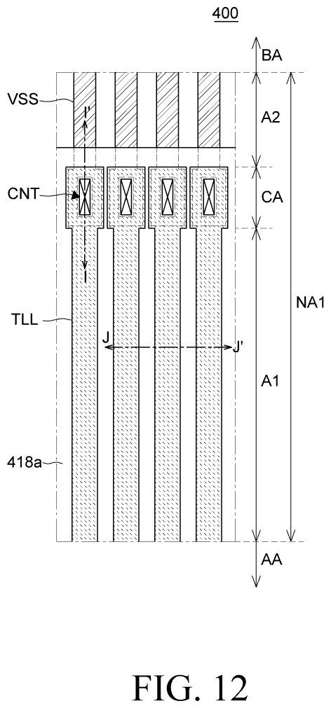

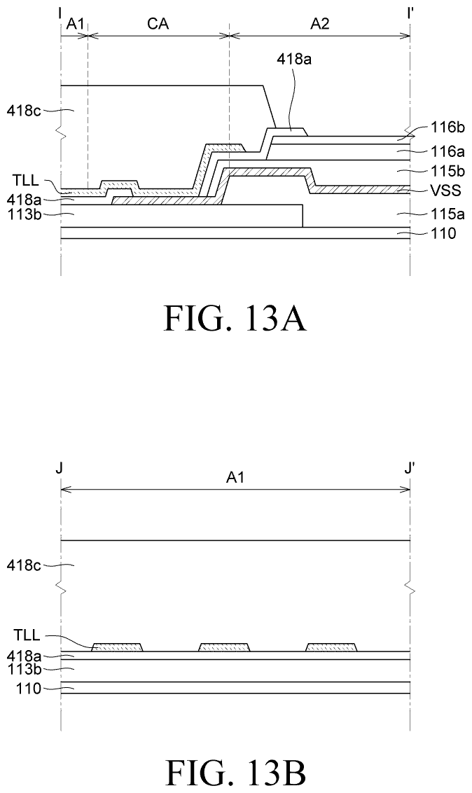

FIG. 12 is a cross-sectional view of a display device according to still another exemplary embodiment of the present disclosure. FIG. 13A is a cross-sectional view taken along I-I′ of FIG. 12. FIG. 13B is a cross-sectional view taken along J-J′ of FIG. 12. In FIG. 12, only a touch buffer layer 418a, a low potential power link line VSS, and a plurality of touch link lines TLL are illustrated for the convenience of description. In FIGS. 13A and 13B, for the convenience of description, only a substrate 110, a second interlayer insulating layer 113b, a first planarization layer 115a, a second planarization layer 115b, a bank layer 116a, a spacer 116b, a touch buffer layer 418a, and a touch planarization layer 418c are illustrated.

Referring to FIGS. 12, 13A, and 13B, the first non-display area NA1 may include a first area A1, a contact area CA, and a second area A2 between a display area and a bending area. Here, the contact area CA is defined as an area in which the plurality of touch link lines TLL and a low potential power link line VSS, among the plurality of power link lines VLL are electrically connected in a plurality of contact holes CNT of the second planarization layer 115b. The first area A1 may be defined as the first non-display area NA1 closer to the display area AA than the plurality of contact holes CNT with respect to the contact area CA. The second area A2 may be defined as the first non-display area NA1 closer to the bending area BA than the plurality of contact holes CNT with respect to the contact area CA.

In the first non-display area NA1, the second interlayer insulating layer 113b is disposed on the substrate 110.

In the second area A2 of the first non-display area NA1, the first planarization layer 115a and the second planarization layer 115b are disposed on the substrate 110 and the second interlayer insulating layer 113b. Specifically, the low potential power link line VSS is disposed on the first planarization layer 115a. The second planarization layer 115b is disposed on the low potential power link line VSS.

In the second area A2, the bank layer 116a and the spacer 116b are disposed on the second planarization layer 115b.

In the first non-display area NA1, the touch buffer layer 418a is disposed on the second interlayer insulating layer 113b. For example, the touch buffer layer 418a may be disposed on the side surface of the second planarization layer 115b on a side of the contact area CA closer to the second area A2. That is, in the first non-display area NA1 closer to the bending area BA than the plurality of contact holes CNT with respect to the contact area CA, the touch buffer layer 418a may be disposed on the side surface of the second planarization layer 115b. In the second area A2, the touch buffer layer 418a may be disposed on the top surface of the second planarization layer 115b along the side surface of the second planarization layer 115b. The touch buffer layer 118a is disposed along a side surface of the second planarization layer 115b in the plurality of contact holes CNT to extend to the top surface of the second planarization layer 115b and top surfaces of the bank layer 116a and the spacer 116b.

In the first non-display area NA1, the plurality of touch link lines TLL is disposed on the touch buffer layer 118a. In the first area A1, the plurality of touch link lines TLL is disposed on the touch buffer layer 418a. In the contact area CA, the plurality of low potential power link lines VSS and the plurality of touch link lines TLL are disposed on the second interlayer insulating layer 113b to be in contact with each other. At this time, the plurality of touch link lines TLL is disposed along the side surface of the second planarization layer 115b to extend to the second area A2 to be disposed on the touch buffer layer 418a.

That is, ends of the plurality of touch link lines TLL are disposed on the touch buffer layer 418a in a part extending from the contact area CA to the second area A2. Therefore, the touch buffer layer 418a is disposed between the second planarization layer 115b and the plurality of touch link lines TLL along the side surface of the second planarization layer 115b.

The touch planarization layer 418c is disposed on the touch link line TLL and the touch buffer layer 418a. In the first non-display area NA1, the touch planarization layer 118c is disposed on the plurality of touch link lines TLL and an end of the touch planarization layer 118c may be disposed on the touch buffer layer 118a. That is, the end of the touch planarization layer 118c may be disposed so as not to be in contact with the end of the touch buffer layer 118a.

Accordingly, in the display device 400 according to another exemplary embodiment of the present disclosure, in the first area A1 of the first non-display area NA1, the plurality of touch link lines TLL and the touch buffer layer 318a are disposed on the second interlayer insulating layer 113b. Therefore, the erroneous operation of the touch electrode unit TE may be improved. Specifically, all the insulating layers disposed in the first area A1 are formed of inorganic layers, so that even though the film lifting is generated in the second area A2, the adhesion of the plurality of touch link lines TLL, the touch buffer layer 318a, and the second interlayer insulating layer 113b in the first area A1 passing the contact area CA is strong. Therefore, the film lifting is not generated. Therefore, in the display device 400 of the present disclosure, the crack generated in the plurality of touch link lines TLL is suppressed to improve the erroneous operation of the touch electrode unit TE. Moreover, the defect of the display device 300 may be minimized.

Further, in the display device 400 according to still another exemplary embodiment of the present disclosure, in an area where the plurality of touch link lines TLL and the plurality of power link lines VSS are electrically connected, the planarization layer which is an organic layer is not disposed in the first non-display area NA1 close to the display area AA. Instead, the plurality of touch link lines TLL and the touch buffer layer 318a are disposed on the second interlayer insulating layer 113b to suppress the crack generated in the plurality of touch link lines TLL and minimize the damage of the touch electrode unit TE. By doing this, the lifespan of the display device 400 is improved to be driven at a low power.

The exemplary embodiments of the present disclosure can also be described as follows:

According to an aspect of the present disclosure, a display device includes: a substrate including a display area, a first non-display area surrounding the display area, a bending area extending from the first non-display area, and a second non-display area extending from the bending area; a plurality of light emitting diodes on the substrate in the display area; a touch electrode unit on the plurality of light emitting diodes in the display area; a plurality of power link lines on the substrate in the first non-display area; a planarization layer on the plurality of power link lines in the first non-display area; a plurality of touch link lines electrically connected to the touch sensing unit and electrically connected to the plurality of power link lines through a plurality of contact holes of the planarization layer in the first non-display area; and a touch buffer layer which is disposed between the plurality of light emitting diodes and the touch sensing unit in the display area and is disposed on the planarization layer in the first non-display area. In the first non-display area which is closer to the display area than the plurality of contact holes of the planarization layer, the plurality of touch link lines and the touch buffer layer are disposed on the same plane on the planarization layer.

In the first non-display area which is closer to the display area than the plurality of contact holes of the planarization layer, the plurality of touch link lines and the touch buffer layer may be alternately disposed.

In the first non-display area which is closer to the display area than the plurality of contact holes of the planarization layer, the touch buffer layer may include a plurality of openings and the plurality of touch link lines may be disposed in the plurality of openings.

The touch buffer layer may be disposed on a side surface of the planarization layer in the plurality of contact holes of the planarization layer and may be disposed in a part of a top surface of the planarization layer adjacent to the plurality of contact holes of the planarization layer.

In the first non-display area which is closer to the display area than the plurality of contact holes of the planarization layer, the plurality of touch link lines may cover an end of the touch buffer layer and may be disposed to be in contact with the planarization layer.

The display device may further include: a bank layer on the planarization layer in the first non-display area closer to the bending area than the plurality of contact holes of the planarization layer; and a touch planarization layer on the touch electrode unit and the plurality of touch link lines. An end of the touch planarization layer and the bank layer may be spaced apart from each other.

The end of the touch planarization layer may be disposed on the touch buffer layer.

The plurality of touch link lines may be disposed to be in contact with a side surface of the planarization layer in the plurality of contact holes of the planarization layer.

In the first non-display area, the touch buffer layer may be disposed on the planarization layer in at least a partial area of an area between the plurality of touch link lines.

In the first non-display area, the touch buffer layer may be disposed in at least a partial area of an area between the plurality of contact holes of the planarization layer.

The display device may further include: a bank layer on the planarization layer in the first non-display area closer to the bending area than the plurality of contact holes of the planarization layer; and a touch planarization layer on the touch electrode unit and the plurality of touch link lines. An end of the touch planarization layer and the bank layer may be spaced apart from each other.

The end of the touch planarization layer may be disposed on the planarization layer.

According to another aspect of the present disclosure, a display device includes: a substrate including a display area, a first non-display area surrounding the display area, a bending area extending from the first non-display area, and a second non-display area extending from the bending area; a plurality of light emitting diodes on the substrate in the display area; an encapsulation unit on the plurality of the light emitting diodes; a touch electrode unit on the encapsulation unit; an insulating layer on the substrate in the first non-display area; a plurality of power link lines on the insulating layer in the first non-display area; a plurality of touch link lines electrically connected to the touch electrode unit in the first non-display area; a planarization layer on the plurality of power link lines in the first non-display area; and a touch insulating layer which is disposed on the touch electrode unit in the display area and is disposed on the planarization layer in the first non-display area. The first non-display area includes a contact area in which the plurality of power link lines and the plurality of touch link lines are electrically connected, and the touch insulating layer is disposed on the insulating layer in a first non-display area of the contact area close to the display area.

The touch insulating layer may be disposed on the planarization layer in a first non-display area of the contact area close to the bending area.

The display device may further include: a bank layer on the planarization layer in the first non-display area of the contact area close to the bending area. An end of the touch insulating layer may be disposed to be in contact with a top surface of the bank layer.

The display device may further include: a touch planarization layer on the touch electrode unit and the plurality of touch link lines. An end of the touch planarization layer may be disposed on the touch buffer layer.

An end of the plurality of touch link lines may be disposed on the touch buffer layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including:
a display area,
a first non-display area adjacent to the display area,
a bending area extending from the first non-display area, and
a second non-display area extending from the bending area;
a plurality of light emitting diodes on the substrate in the display area;
a touch electrode unit on the plurality of light emitting diodes in the display area;
a plurality of power link lines on the substrate in the first non-display area;
a planarization layer on the plurality of power link lines in the first non-display area;
a plurality of contact holes of the planarization layer in the first non-display area;
a plurality of touch link lines electrically connected to the touch electrode unit and electrically connected to the plurality of power link lines through the plurality of contact holes of the planarization layer in the first non-display area; and
a touch buffer layer between the plurality of light emitting diodes and the touch electrode unit in the display area and on the planarization layer in the first non-display area,
wherein in the first non-display area which is closer to the display area than the plurality of contact holes of the planarization layer, the plurality of touch link lines and the touch buffer layer are on the same surface of the planarization layer.

2. The display device according to claim 1, wherein in the first non-display area which is closer to the display area than the plurality of contact holes of the planarization layer, the plurality of touch link lines and the touch buffer layer are alternately disposed.

3. The display device according to claim 1, further comprising: a plurality of openings included in the touch buffer layer,
wherein in the first non-display area which is closer to the display area than the plurality of contact holes of the planarization layer, and the plurality of touch link lines is disposed in the plurality of openings.

4. The display device according to claim 1, wherein the touch buffer layer is disposed on a side surface of the planarization layer in the plurality of contact holes of the planarization layer and is disposed in a part of a top surface of the planarization layer adjacent to the plurality of contact holes of the planarization layer.

5. The display device according to claim 4, wherein in the first non-display area which is closer to the display area than the plurality of contact holes of the planarization layer, the plurality of touch link lines covers an end of the touch buffer layer and is disposed to be in contact with the planarization layer.

6. The display device according to claim 4, further comprising:
a bank layer on the planarization layer in the first non-display area closer to the bending area than the plurality of contact holes of the planarization layer; and
a touch planarization layer on the touch electrode unit and the plurality of touch link lines,
wherein an end of the touch planarization layer and the bank layer are spaced apart from each other.

7. The display device according to claim 6, wherein the end of the touch planarization layer is disposed on the touch buffer layer.

8. The display device according to claim 1, wherein the plurality of touch link lines is disposed to be in contact with a side surface of the planarization layer in the plurality of contact holes of the planarization layer.

9. The display device according to claim 8, wherein in the first non-display area, the touch buffer layer is disposed on the planarization layer in at least a partial area of an area between the plurality of touch link lines.

10. The display device according to claim 8, wherein in the first non-display area, the touch buffer layer is disposed in at least a partial area of an area between the plurality of contact holes of the planarization layer.

11. The display device according to claim 8, further comprising:
a bank layer on the planarization layer in the first non-display area closer to the bending area than the plurality of contact holes of the planarization layer; and
a touch planarization layer on the touch electrode unit and the plurality of touch link lines,
wherein an end of the touch planarization layer and the bank layer are spaced apart from each other.

12. The display device according to claim 11, wherein the end of the touch planarization layer is on the planarization layer.

13. A display device, comprising:
a substrate including:
a display area,
a first non-display area adjacent to the display area,
a bending area extending from the first non-display area, and
a second non-display area extending from the bending area;
a plurality of light emitting diodes on the substrate in the display area;
an encapsulation unit on the plurality of the light emitting diodes;
a touch electrode unit on the encapsulation unit;
an insulating layer on the substrate in the first non-display area;
a plurality of power link lines on the insulating layer in the first non-display area;
a plurality of touch link lines electrically connected to the touch electrode unit in the first non-display area;
a planarization layer on the plurality of power link lines in the first non-display area; and
a touch insulating layer which is disposed on the touch electrode unit in the display area and is disposed on the planarization layer in the first non-display area,
wherein the first non-display area includes a contact area in which the plurality of power link lines and the plurality of touch link lines are electrically connected, and
wherein the touch insulating layer is on the insulating layer in a first non-display area of the contact area close to the display area.

14. The display device according to claim 13, wherein the touch insulating layer is on the planarization layer in a first non-display area of the contact area close to the bending area.

15. The display device according to claim 14, further comprising:
a bank layer on the planarization layer in the first non-display area of the contact area close to the bending area,
wherein an end of the touch insulating layer is disposed to be in contact with a top surface of the bank layer.

16. The display device according to claim 15, further comprising:
a touch planarization layer on the touch electrode unit and the plurality of touch link lines,
wherein an end of the touch planarization layer is disposed on the touch buffer layer.

17. The display device according to claim 14, wherein an end of the plurality of touch link lines is on the touch buffer layer.
